(19) United States
(12) Patent Application Publication
(10) Pub. No.: US 2020/0082862 A1
(43) Pub. Date: Mar. 12, 2020

(54) SEMICONDUCTOR PACKAGES

(71) Applicant: SK hynix Inc., Icheon-si Gyeonggi-do (KR)

(72) Inventors: Woongrae KIM, Icheon-si Gyeonggi-do (KR); Bok Rim KO, Seoul (KR); Ki Up KIM, Cheongju-si Chungcheongbuk-do (KR); Yoo Jong LEE, Suwon-si Gyeonggi-do (KR)

(73) Assignee: SK hynix Inc., Icheon-si Gyeonggi-do (KR)

(21) Appl. No.: 16/219,624

(22) Filed: Dec. 13, 2018

(30) Foreign Application Priority Data
Sep. 6, 2018 (KR) 10-2018-0106652

(51) Int. Cl. G11C 11/16; H01L 27/108; H01L 25/065

(52) U.S. Cl. CPC G11C 11/1653; G11C 11/1673; H01L 25/0657; H01L 27/108; G11C 11/1675

(57) ABSTRACT

A semiconductor package includes a first semiconductor chip and a second semiconductor chip. The first semiconductor chip has a first pad region located at a first region of the first semiconductor chip and a second pad region located at a second region of the first semiconductor chip. The second semiconductor chip has a third pad region located at a first region of the second semiconductor chip and a fourth pad region located at a second region of the second semiconductor chip. The second semiconductor chip is stacked on the first semiconductor chip to be offset in a first lateral direction relative to the first semiconductor chip.

### CROSS-REFERENCE TO RELATED APPLICATIONS

The present application claims priority under 35 U.S.C 119(a) to Korean Application No. 10-2018-0106652, filed on Sep. 6, 2018, which is incorporated herein by reference in its entirety.

### BACKGROUND

### 1. Technical Field

Embodiments of the present disclosure generally relate to semiconductor packages including a plurality of semiconductor chips that are vertically stacked.

### 2. Related Art

In general, each semiconductor device such as a dynamic random access memory (DRAM) device may include a plurality of bank groups comprised of cell arrays which are selected by addresses. Each of the bank groups may be realized to include a plurality of banks. The semiconductor device may select any one of the plurality of bank groups and may perform a column operation for outputting data stored in a cell array included in the selected bank group through input/output (I/O) lines. The semiconductor devices (also, referred to as semiconductor chips) may be vertically stacked on a package substrate and may be encapsulated with a molding layer to provide a semiconductor package. Recently, various techniques for stacking the semiconductor chips have been proposed to improve the performance of the semiconductor package.

FIG. 1 is a cross-sectional view illustrating a conventional semiconductor package including a plurality of semiconductor chips that are vertically stacked.

Referring to FIG. 1, the conventional semiconductor package may include first to third semiconductor chips 200, 300 and 400 which are vertically stacked. The first semiconductor chip 200 is stacked on a surface of a package substrate 100. The first semiconductor chip 200 includes a first body and pads P disposed on a top surface of the first body opposite to the substrate 100, and the pads P are electrically connected to the package substrate 100 through wires W.

The second semiconductor chip 300 is stacked over a top surface of the first semiconductor chip 200 opposite to the package substrate 100. The second semiconductor chip 300 includes a second body and pads P disposed on a top surface of the second body opposite to the first semiconductor chip 200, and the pads P of the second semiconductor chip 300 are electrically connected to the package substrate 100 through the wires W.

The third semiconductor chip 400 is stacked over a top surface of the second semiconductor chip 300 opposite to the first semiconductor chip 200. The third semiconductor chip 400 includes a third body and pads P disposed on a top surface of the third body opposite to the second semiconductor chip 300, and the pads P of the third semiconductor chip 400 are electrically connected to the package substrate 100 through the wires W.

In the conventional semiconductor package illustrated in FIG. 1, there are limitations in reducing a distance H between the first to third semiconductor chips 200, 300 and 400 because of the presence of the wires W that are disposed to electrically connect the first to third semiconductor chips 200, 300 and 400 with the substrate 100.

### SUMMARY

According to an embodiment, a semiconductor package may include a first semiconductor chip and a second semiconductor chip. The first semiconductor chip may have a first pad region located at a first region of the first semiconductor chip and a second pad region located at a second region of the first semiconductor chip. The second semiconductor chip may have a third pad region located at a first region of the second semiconductor chip and a fourth pad region located at a second region of the second semiconductor chip. The second semiconductor chip may be stacked on the first semiconductor chip to be offset in a first lateral direction relative to the first semiconductor chip.

According to an embodiment, a semiconductor package may include a first semiconductor chip, a second semiconductor chip, a third semiconductor chip and a fourth semiconductor chip. The first semiconductor chip may be configured to include a first pad region extending in a first direction and a second pad region extending in a second direction intersecting the first direction, configured to receive a command and an address through the first pad region, and configured to receive or output data through the first pad region. The second semiconductor chip may be configured to include a third pad region extending in the first direction and a second pad region extending in the second direction, configured to receive the command and the address through the third pad region, and configured to receive or output the data through the third pad region. The third semiconductor chip may be configured to include a fifth pad region extending in the first direction and a sixth pad region extending in the second direction, configured to receive the command and the address through the fifth pad region, and configured to receive or output the data through the fifth pad region. The fourth semiconductor chip may be configured to include a seventh pad region extending in the first direction and an eighth pad region extending in the second direction, configured to receive the command and the address through the seventh pad region, and configured to receive or output the data through the seventh pad region. The second, third and fourth semiconductor chips maybe sequentially and vertically stacked on the first semiconductor chip in a zigzag fashion.

### BRIEF DESCRIPTION OF THE DRAWINGS

FIG. 1 is a cross-sectional view illustrating a configuration of a conventional semiconductor package.

FIG. 2 is a cross-sectional view illustrating a configuration of a semiconductor package according to an embodiment of the present disclosure.

FIG. 3 is a plan view illustrating a configuration of a first semiconductor chip included in the semiconductor package of FIG. 2.

FIG. 4 is a plan view illustrating a configuration of a second semiconductor chip included in the semiconductor package of FIG. 2.

FIG. 5 is a block diagram illustrating a configuration of a first memory region included in the first semiconductor chip of FIG. 3.

FIG. 6 is a block diagram illustrating a configuration of a second memory region included in the first semiconductor chip of FIG. 3.

FIG. 7 is a plan view illustrating a stack status of a first semiconductor chip and a second semiconductor chip included in a semiconductor package according to an embodiment of the present disclosure.

FIG. 8 is a block diagram illustrating a configuration of an electronic system including the semiconductor package illustrated in FIGS. 1 to 7.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

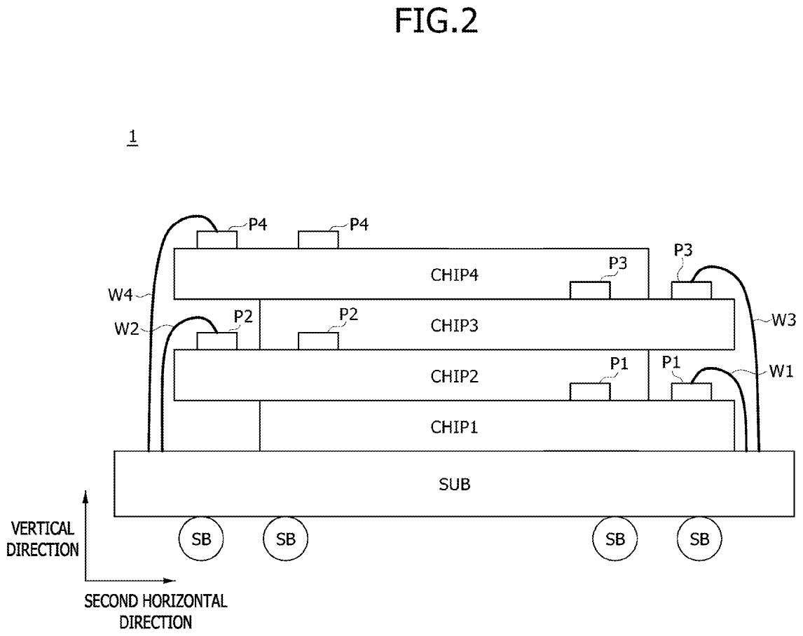

As illustrated in FIG. 2, a semiconductor package 1 according to an embodiment may include a substrate SUB, a first semiconductor chip CHIP1, a second semiconductor chip CHIP2, a third semiconductor chip CHIP3 and a fourth semiconductor chip CHIP4.

The substrate SUB may include a plurality of solder balls SB. The substrate SUB may receive signals from an external device through the solder balls SB or may output the signals to the external device through the solder balls SB.

The first semiconductor chip CHIP1 may be stacked on a surface of the substrate SUB. The first semiconductor chip CHIP1 may include a first body and first pads P1 disposed on a top surface of the first body opposite to the substrate SUB. The first pads P1 may be electrically connected to the substrate SUB through first wires W1. Accordingly, the first semiconductor chip CHIP1 may receive signals from the substrate SUB or may output the signals to the substrate SUB through the first pads P1 and the first wires W1.

The second semiconductor chip CHIP2 may be stacked on a top surface of the first semiconductor chip CHIP1 opposite to the substrate SUB. The second semiconductor chip CHIP2 may include a second body and second pads P2 disposed on a top surface of the second body opposite to the first semiconductor chip CHIP1. The second pads P2 may be electrically connected to the substrate SUB through second wires W2. Accordingly, the second semiconductor chip CHIP2 may receive signals from the substrate SUB or may output the signals to the substrate SUB through the second pads P2 and the second wires W2.

The third semiconductor chip CHIP3 may be stacked on a top surface of the second semiconductor chip CHIP2 opposite to the first semiconductor chip CHIP1. The third semiconductor chip CHIP3 may include a third body and third pads P3 disposed on a top surface of the third body opposite to the second semiconductor chip CHIP2. The third pads P3 may be electrically connected to the substrate SUB through third wires W3. Accordingly, the third semiconductor chip CHIP3 may receive signals from the substrate SUB or may output the signals to the substrate SUB through the third pads P3 and the third wires W3.

The fourth semiconductor chip CHIP4 may be stacked on a top surface of the third semiconductor chip CHIP3 opposite to the second semiconductor chip CHIP2. The fourth semiconductor chip CHIP4 may include a fourth body and fourth pads P4 disposed on a top surface of the fourth body opposite to the third semiconductor chip CHIP3. The fourth pads P4 may be electrically connected to the substrate SUB through fourth wires W4. Accordingly, the fourth semiconductor chip CHIP4 may receive signals from the substrate SUB or may output the signals to the substrate SUB through the fourth pads P4 and the fourth wires W4.

The first to fourth semiconductor chips CHIP1, CHIP2, CHIP3 and CHIP4 may be vertically stacked on the substrate SUB in a zigzag fashion to expose the first to fourth pads P1, P2, P3 and P4 which are disposed on edges of the first to fourth bodies of the first to fourth semiconductor chips CHIP1, CHIP2, CHIP3 and CHIP4.

For example, the second semiconductor chip CHIP2 may be rotated by 180 degrees using the first semiconductor chip CHIP1 as a reference chip in a plan view, and the rotated second semiconductor chip CHIP2 may be stacked on the first semiconductor chip CHIP1 to be laterally offset relative to the first semiconductor chip CHIP1 such that the first pads P1 of the first semiconductor chip CHIP1 are exposed. The third semiconductor chip CHIP3 may be rotated by 180 degrees using the second semiconductor chip CHIP2 as a reference chip in a plan view, and the rotated third semiconductor chip CHIP3 may be stacked on the second semiconductor chip CHIP2 to be laterally offset relative to the second semiconductor chip CHIP2 such that the second pads P2 of the second semiconductor chip CHIP2 are exposed. The fourth semiconductor chip CHIP4 may be rotated by 180 degrees using the third semiconductor chip CHIP3 as a reference chip in a plan view, and the rotated fourth semiconductor chip CHIP4 may be stacked on the third semiconductor chip CHIP3 to be laterally offset relative to the third semiconductor chip CHIP3 such that the third pads P3 of the third semiconductor chip CHIP3 are exposed. That is, the second semiconductor chip CHIP2 may be stacked to be offset in a first offset direction relative to the first semiconductor chip CHIP1 to provide a space for bonding the first wires W1 to the first pads P1, and the third semiconductor chip CHIP3 may be stacked to be offset in a second offset direction opposite to the first offset direction relative to the second semiconductor chip CHIP2 to provide a space for bonding the second wires W2 to the second pads P2. In addition, the fourth semiconductor chip CHIP4 may be stacked to be offset in the first offset direction relative to the third semiconductor chip CHIP3 to provide a space for bonding the third wires W3 to the third pads P3. Accordingly, the first to fourth semiconductor chips CHIP1, CHIP2, CHIP3 and CHIP4 may be vertically stacked on the substrate SUB in a zigzag fashion to expose the first to fourth pads P1, P2, P3 and P4.

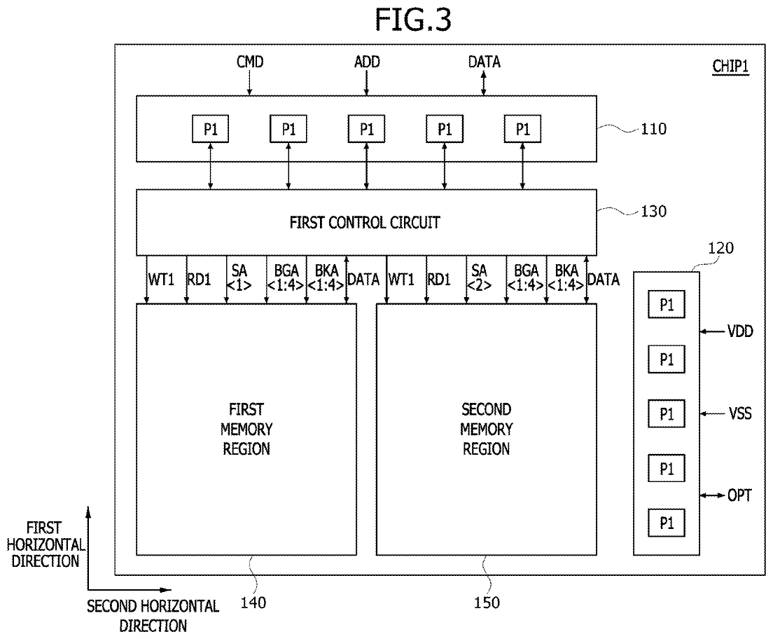

Referring to FIG. 3, the first semiconductor chip CHIP1 may include a first pad region 110, a second pad region 120, a first control circuit 130, a first memory region 140 and a second memory region 150.

The first pad region 110 may be located at a first region of the first semiconductor chip CHIP1. The first region may correspond to any one among four edge regions of the first semiconductor chip CHIP1, for example, a first edge region (corresponding to an upper edge region in a plan view of FIG. 3) when viewed from a plan view.

The first pad region 110 may include some of the first pads P1, and some of these first pads P1 in the first pad region 110 may be electrically connected to the substrate SUB through some of the first wires W1. A command CMD and an address ADD may be inputted to the first semiconductor chip CHIP1 through the first pads P1 in the first pad region 110. Data DATA may also be inputted to or outputted from the first semiconductor chip CHIP1 through the first pads P1 in the first pad region 110.

The second pad region 120 may be located at a second region of the first semiconductor chip CHIP1. The second region may correspond to another one among four edge regions of the first semiconductor chip CHIP1, for example, a second edge region (corresponding to a right edge region in a plan view of FIG. 3) when viewed from a plan view. In some other embodiments, the second region may be set as a left edge region in a plan view of FIG. 3. While the first pads P1 in the first pad region 110 are arrayed in a second horizontal direction in FIG. 3, the first pads P1 in the second pad region 120 may be arrayed in a first horizontal direction perpendicular to the second horizontal direction.

The second pad region 120 may include some of the first pads P1, and some of these first pads P1 in the second pad region 120 may be electrically connected to the substrate SUB through some of the first wires W1. A power supply voltage VDD, a ground voltage VSS and optional information OPT may be inputted to the first semiconductor chip CHIP1 through the first pads P1 in the second pad region 120. The power supply voltage VDD and the ground voltage VSS may be supplied to the first semiconductor chip CHIP1 through the first pads P1 in the second pad region 120. The optional information OPT corresponding to operational information of the first semiconductor chip CHIP1 may be inputted to the first semiconductor chip CHIP1 through the first pads P1 in the second pad region 120. The optional information OPT may include various pieces of information for performing operations of the first semiconductor chip CHIP1. For example, the optional information OPT may include information on a “×4” mode, information on a “×8” mode, information on a “×16” mode or the like for setting the number of bits included the data DATA that are inputted to or outputted from the first semiconductor chip CHIP1 through the first pad region 110.

Signals transmitted through the first and second pad regions 110 and 120 may be set to be different according to the embodiments.

The first pad region 110 and the second pad region 120 may be disposed to be perpendicular to each other in a plan view. In some embodiments, first pad region 110 and the second pad region 120 may be disposed to be substantially perpendicular to each other in a plan view. In some embodiments, first pad region 110 and the second pad region 120, if extended out, may be disposed to intersect each other in a plan view.

The first control circuit 130 may be disposed between the first pad region 110 and a memory region including the first and second memory regions 140 and 150.

The first control circuit 130 may receive the command CMD through the first pad region 110 and may decode the command CMD to generate a first write signal WT1 and a first read signal RD1. The first control circuit 130 may receive the address ADD through the first pad region 110 and may decode the address ADD to generate first and second selection addresses SA<1:2>, first to fourth bank group addresses BGA<1:4>, and first to fourth bank addresses BKA<1:4>. The first control circuit 130 may receive or output the data DATA through the first pad region 110.

The first semiconductor chip CHIP1 may provide a bank group mode, an 8-bank mode and a 16-bank mode. A bank group may include a plurality of banks. For example, the bank group may include four banks. In the bank group mode, a column operation for one bank included in the bank group may be performed by one command. In the 8-bank mode, column operations for two banks respectively included in two separate bank groups are sequentially performed by one command. In the 16-bank mode, column operations for four banks respectively included in four separate bank groups are sequentially performed by one command.

In the 8-bank mode, the first control circuit 130 may generate two bank group addresses among the first to fourth bank group addresses BGA<1:4>. For example, the first and third bank group addresses BGA<1> and BGA<3> may be simultaneously enabled in the 8-bank mode. In the 16-bank mode, the first control circuit 130 may generate one bank group address of the first to fourth bank group addresses BGA<1:4>. For example, the first to fourth bank group addresses BGA<1:4> may be sequentially enabled in the 16-bank mode.

The first memory region 140 may be located at one side of the first control circuit 130 opposite to the first pad region 110 in a plan view.

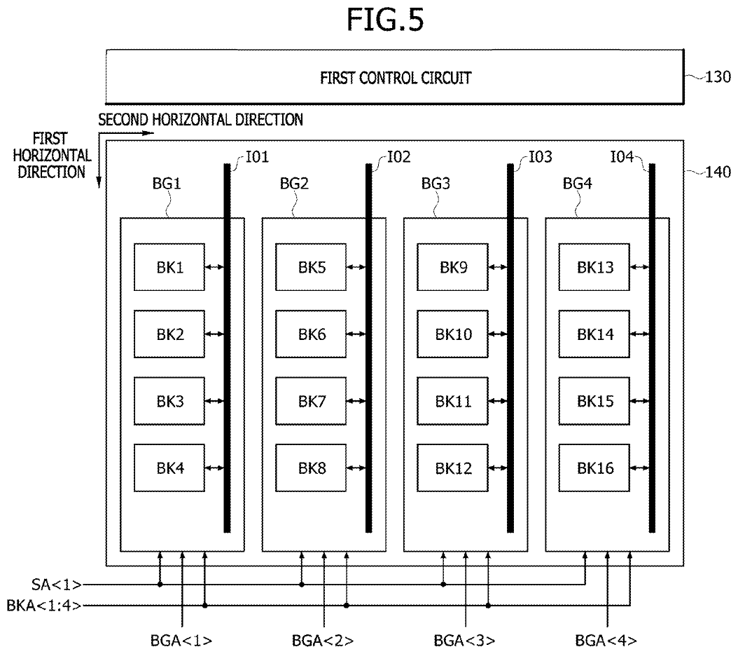

The first memory region 140 may include first to fourth bank groups (BG1, BG2, BG3 and BG4 of FIG. 5) which are activated according to the first to fourth bank group addresses BGA<1:4> if the first selection address SA<1> is enabled. The first to fourth bank groups (BG1, BG2, BG3 and BG4 of FIG. 5) may include first to sixteenth banks (BK1˜BK16 of FIG. 5) which are activated according to the first to fourth bank addresses BKA<1:4>. The first memory region 140 may store the data DATA into the first to fourth bank groups (BG1, BG2, BG3 and BG4 of FIG. 5) which are activated according to the first to fourth bank group addresses BGA<1:4> if the first write signal WT1 is enabled and the first selection address SA<1> is enabled. The first memory region 140 may output the data DATA stored in the first to fourth bank groups (BG1, BG2, BG3 and BG4 of FIG. 5) which are activated according to the first to fourth bank group addresses BGA<1:4> if the first read signal RD1 is enabled and the first selection address SA<1> is enabled.

The first memory region 140 may activate two bank groups among the first to fourth bank groups (BG1, BG2, BG3 and BG4 of FIG. 5) according to the first to fourth bank group addresses BGA<1:4> to receive or output the data DATA if the first selection address SA<1> is enabled in the 8-bank mode. The first memory region 140 may activate one bank group among the first to fourth bank groups (BG1, BG2, BG3 and BG4 of FIG. 5) according to the first to fourth bank group addresses BGA<1:4> to receive or output the data DATA if the first selection address SA<1> is enabled in the 16-bank mode. The number of bits included in the data DATA inputted or outputted whenever a write operation or a read operation is performed once may be set to have a burst length of “16” or “32”.

The second memory region 150 may be located at one side of the first control circuit 130 opposite to the first pad region 110 in a plan view.

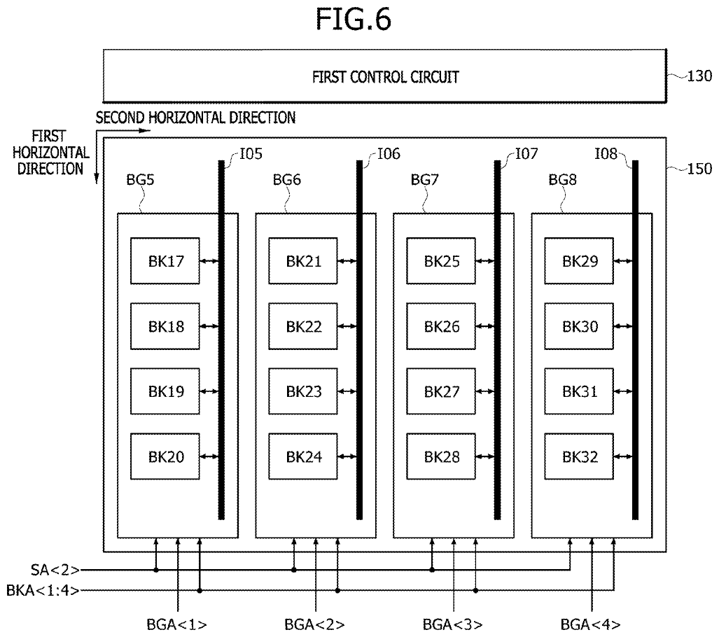

The second memory region 150 may include fifth to eighth bank groups (BG5, BG6, BG7 and BG8 of FIG. 6) which are activated according to the first to fourth bank group addresses BGA<1:4> if the second selection address SA<2> is enabled. The fifth to eighth bank groups (BG5, BG6, BG7 and BG8 of FIG. 6) may include seventeenth to thirty-second banks (BK17˜BK32 of FIG. 6) which are activated according to the first to fourth bank addresses BKA<1:4>. The second memory region 150 may store the data DATA into the fifth to eighth bank groups (BG5, BG6, BG7 and BG8 of FIG. 6) which are activated according to the first to fourth bank group addresses BGA<1:4> if the first write signal WT1 is enabled and the second selection address SA<2> is enabled. The second memory region 150 may output the data DATA stored in the fifth to eighth bank groups (BG5, BG6, BG7 and BG8 of FIG. 6) which are activated according to the first to fourth bank group addresses BGA<1:4> if the first read signal RD1 is enabled and the second selection address SA<2> is enabled.

The second memory region 150 may activate two bank groups among the fifth to eighth bank groups (BG5, BG6, BG7 and BG8 of FIG. 6) according to the first to fourth bank group addresses BGA<1:4> to receive or output the data DATA if the second selection address SA<2> is enabled in the 8-bank mode. The second memory region 150 may activate one bank group among the fifth to eighth bank groups (BG5, BG6, BG7 and BG8 of FIG. 6) according to the first to fourth bank group addresses BGA<1:4> to receive or output the data DATA if the second selection address SA<2> is enabled in the 16-bank mode. The number of bits included in the data DATA inputted or outputted whenever the write operation or the read operation is performed once may be set to have a burst length of “16” or “32”.

The first and second memory regions 140 and 150 may be located at one side of the first control circuit 130 opposite to the first pad region 110 to be adjacent to each other in a plan view.

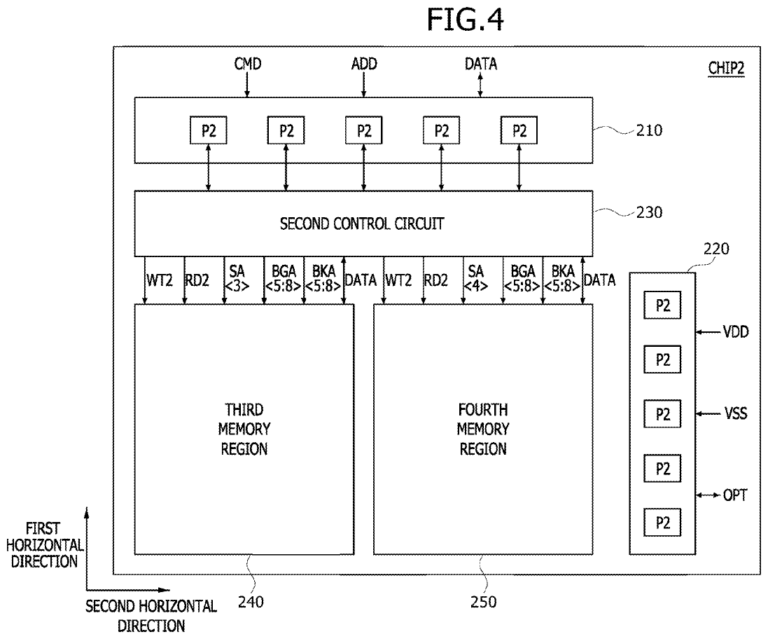

Referring to FIG. 4, the second semiconductor chip CHIP2 may include a third pad region 210, a fourth pad region 220, a second control circuit 230, a third memory region 240 and a fourth memory region 250.

The third pad region 210 may be located at a first region of the second semiconductor chip CHIP2. The first region of the second semiconductor chip CHIP2 may correspond to any one among four edge regions of the second semiconductor chip CHIP2, for example, a first edge region (corresponding to an upper edge region in a plan view of FIG. 3) when viewed from a plan view.

The third pad region 210 may include some of the second pads P2, and the second pads P2 in the third pad region 210 may be electrically connected to the substrate SUB through some of the second wires W2. The third pad region 210 may be configured to have substantially the same function as the first pad region 110. Thus, descriptions of the third pad region 210 will be omitted hereinafter.

The fourth pad region 220 may be located at a second region of the second semiconductor chip CHIP2. The second region of the second semiconductor chip CHIP2 may correspond to another one among the four edge regions of the second semiconductor chip CHIP2, for example, a second edge region (corresponding to a right edge region in a plan view of FIG. 4) when viewed from a plan view. While the second pads P2 in the third pad region 210 are arrayed in a second horizontal direction in FIG. 4, the second pads P2 in the fourth pad region 220 may be arrayed in a first horizontal direction perpendicular to the second horizontal direction.

The fourth pad region 220 may include some of the second pads P2, and some of these second pads P2 in the fourth pad region 220 may be electrically connected to the substrate SUB through some of the second wires W2. The fourth pad region 220 may be configured to have substantially the same function as the second pad region 120. Thus, detailed descriptions of the fourth pad region 220 will be omitted hereinafter.

Signals transmitted through the third and fourth pad regions 210 and 220 may be set to be different according to the embodiments.

The third pad region 210 and the fourth pad region 220 may be disposed to be perpendicular to each other in a plan view. In some embodiments, third pad region 210 and the fourth pad region 220 may be disposed to be substantially perpendicular to each other in a plan view. In some embodiments, third pad region 210 and the fourth pad region 220, if extended out, may be disposed to intersect each other in a plan view.

The second control circuit 230 may be disposed between the third pad region 210 and a memory region including the third and fourth memory regions 240 and 250.

The second control circuit 230 may receive the command CMD through the third pad region 210 and may decode the command CMD to generate a second write signal WT2 and a second read signal RD2. The second control circuit 230 may receive the address ADD through the third pad region 210 and may decode the address ADD to generate third and fourth selection addresses SA<3:4>, fifth to eighth bank group addresses BGA<5:8>, and fifth to eighth bank addresses BKA<5:8>. The second control circuit 230 may receive or output the data DATA through the third pad region 210.

The second control circuit 230 may be realized to perform substantially the same operation as the first control circuit 130. Thus, descriptions of the second control circuit 230 will be omitted hereinafter.

The third memory region 240 may be located at one side of the second control circuit 230 opposite to the third pad region 210 in a plan view.

The third memory region 240 may include ninth to twelfth bank groups (not shown) which are activated according to the fifth to eighth bank group addresses BGA<5:8> if the third selection address SA<3> is enabled. The ninth to twelfth bank groups (not shown) may include thirty-third to forty-eighth banks (not shown) which are activated according to the fifth to eighth bank addresses BKA<5:8>.

The third memory region 240 may be realized to have substantially the same configuration as the first memory region 140 except input/output (I/O) signals thereof. Thus, descriptions of the third memory region 240 will be omitted hereinafter.

The fourth memory region 250 may be located at one side of the second control circuit 230 opposite to the third pad region 210 in a plan view.

The fourth memory region 250 may include thirteenth to sixteenth bank groups (not shown) which are activated according to the fifth to eighth bank group addresses BGA<5:8> if the fourth selection address SA<4> is enabled. The thirteenth to sixteenth bank groups (not shown) may include forty-ninth to sixty-fourth banks (not shown) which are activated according to the fifth to eighth bank addresses BKA<5:8>.

The fourth memory region 250 may be realized to have substantially the same configuration as the second memory region 150 except input/output (I/O) signals thereof. Thus, descriptions of the fourth memory region 250 will be omitted hereinafter.

Referring to FIG. 5, the first memory region 140 may include the first bank group BG1, the second bank group BG2, the third bank group BG3 and the fourth bank group BG4.

The first bank group BG1 may include the first to fourth banks BK1, BK2, BK3 and BK4.

The first bank BK1 may be activated if the first selection address SA<1>, the first bank group address BGA<1> and the first bank address BKA<1> are enabled. The second bank BK2 may be activated if the first selection address SA<1>, the first bank group address BGA<1> and the second bank address BKA<2> are enabled. The third bank BK3 may be activated if the first selection address SA<1>, the first bank group address BGA<1> and the third bank address BKA<3> are enabled. The fourth bank BK4 may be activated if the first selection address SA<1>, the first bank group address BGA<1> and the fourth bank address BKA<4> are enabled. The first to fourth banks BK1, BK2, BK3 and BK4 may share a first I/O line 101 with each other and may receive or output the data DATA through the first I/O line 101. That is, the first bank group BG1 may be coupled to the first I/O line 101 to receive or output the data DATA through the first I/O line 101.

The second bank group BG2 may include the fifth to eighth banks BK5, BK6, BK7 and BK8.

The second bank group BG2 may be activated if the second bank group address BGA<2> is enabled, and the fifth to eighth banks BK5, BK6, BK7 and BK8 may share a second I/O line 102 with each other to receive or output the data DATA through the second I/O line 102. The fifth to eighth banks BK5, BK6, BK7 and BK8 may be configured to perform substantially the same operations as the first to fourth banks BK1, BK2, BK3 and BK4. Thus, descriptions of the second bank group BG2 will be omitted hereinafter.

The third bank group BG3 may include the ninth to twelfth banks BK9, BK10, BK11 and BK12.

The third bank group BG3 may be activated if the third bank group address BGA<3> is enabled, and the ninth to twelfth banks BK9, BK10, BK11 and BK12 may share a third I/O line 103 with each other to receive or output the data DATA through the third I/O line 103. The ninth to twelfth banks BK9, BK10, BK11 and BK12 may be configured to perform substantially the same operations as the first to fourth banks BK1, BK2, BK3 and BK4. Thus, descriptions of the third bank group BG3 will be omitted hereinafter.

The fourth bank group BG4 may include the thirteenth to sixteenth banks BK13, BK14, BK15 and BK16.

The fourth bank group BG4 may be activated if the fourth bank group address BGA<4> is enabled, and the thirteenth to sixteenth banks BK13, BK14, BK15 and BK16 may share a fourth I/O line 104 with each other to receive or output the data DATA through the fourth I/O line 104. The thirteenth to sixteenth banks BK13, BK14, BK15 and BK16 may be configured to perform substantially the same operations as the first to fourth banks BK1, BK2, BK3 and BK4. Thus, descriptions of the fourth bank group BG4 will be omitted hereinafter.

The first memory region 140 may activate two banks among the first to sixteenth banks BK1˜BK16 to receive or output the data DATA in the 8-bank mode. For example, the first and third bank group addresses BGA<1> and BGA<3> may be enabled in the 8-bank mode, and the first bank BK1 and the ninth bank BK9 may be activated to receive or output the data DATA if the first bank address BKA<1> is enabled.

The first to fourth bank groups BG1, BG2, BG3 and BG4 may be arrayed in a second horizontal direction of the first memory region 140 in a plan view. The first to fourth banks BK1˜BK4 included in the first bank group BG1 may be arrayed in a first horizontal direction of the first memory region 140 in a plan view. The fifth to eighth banks BK5˜BK8 included in the second bank group BG2 may be arrayed in the first horizontal direction of the first memory region 140 in a plan view. The ninth to twelfth banks BK9˜BK12 included in the third bank group BG3 may be arrayed in the first horizontal direction of the first memory region 140 in a plan view. The thirteenth to sixteenth banks BK13˜BK16 included in the fourth bank group BG4 may be arrayed in the first horizontal direction of the first memory region 140 in a plan view.

Referring to FIG. 6, the second memory region 150 may include the fifth bank group BG5, the sixth bank group BG6, the seventh bank group BG7 and the eighth bank group BG8.

The fifth bank group BG5 may include the seventeenth to twentieth banks BK17, BK18, BK19 and BK20.

The seventeenth BK17 may be activated if the second selection address SA<2>, the first bank group address BGA<1> and the first bank address BKA<1> are enabled. The eighteenth bank BK18 may be activated if the second selection address SA<2>, the first bank group address BGA<1> and the second bank address BKA<2> are enabled. The nineteenth bank BK19 may be activated if the second selection address SA<2>, the first bank group address BGA<1> and the third bank address BKA<3> are enabled. The twentieth bank BK20 may be activated if the second selection address SA<2>, the first bank group address BGA<1> and the fourth bank address BKA<4> are enabled. The seventeenth to twentieth banks BK17, BK18, BK19 and BK20 may share a fifth I/O line 105 with each other and may receive or output the data DATA through the fifth I/O line 105. That is, the fifth bank group BG5 may be coupled to the fifth I/O line 105 to receive or output the data DATA through the fifth I/O line 105.

The sixth bank group BG6 may include the twenty-first to twenty-fourth banks BK21, BK22, BK23 and BK24.

The sixth bank group BG6 may be activated if the second bank group address BGA<2> is enabled, and the twenty-first to twenty-fourth banks BK21, BK22, BK23 and BK24 may share a sixth I/O line 106 with each other to receive or output the data DATA through the sixth I/O line 106. The twenty-first to twenty-fourth banks BK21, BK22, BK23 and BK24 may be configured to perform substantially the same operations as the seventeenth to twentieth banks BK17, BK18, BK19 and BK20. Thus, descriptions of the sixth bank group BG6 will be omitted hereinafter.

The seventh bank group BG7 may include the twenty-fifth to twenty-eighth banks BK25, BK26, BK27 and BK28.

The seventh bank group BG7 may be activated if the third bank group address BGA<3> is enabled, and the twenty-fifth to twenty-eighth banks BK25, BK26, BK27 and BK28 may share a seventh I/O line 107 with each other to receive or output the data DATA through the seventh I/O line 107. The twenty-fifth to twenty-eighth banks BK25, BK26, BK27 and BK28 may be configured to perform substantially the same operations as the seventeenth to twentieth banks BK17, BK18, BK19 and BK20. Thus, descriptions of the seventh bank group BG7 will be omitted hereinafter.

The eighth bank group BG8 may include the twenty-ninth to thirty-second banks BK29, BK30, BK31 and BK32.

The eighth bank group BG8 may be activated if the fourth bank group address BGA<4> is enabled, and the twenty-ninth to thirty-second banks BK29, BK30, BK31 and BK32 may share an eighth I/O line 108 with each other to receive or output the data DATA through the eighth I/O line 108. The twenty-ninth to thirty-second banks BK29, BK30, BK31 and BK32 may be configured to perform substantially the same operations as the seventeenth to twentieth banks BK17, BK18, BK19 and BK20. Thus, descriptions of the eighth bank group BG8 will be omitted hereinafter.

The second memory region 150 may activate two banks among the seventeenth to thirty-second banks BK17˜BK32 to receive or output the data DATA in the 8-bank mode. For example, the first and third bank group addresses BGA<1> and BGA<3> may be enabled in the 8-bank mode, and the seventeenth bank BK17 and the twenty-fifth bank BK25 may be activated to receive or output the data DATA if the first bank address BKA<1> is enabled.

The fifth to eighth bank groups BG5, BG6, BG7 and BG8 may be arrayed in a second horizontal direction of the second memory region 150 in a plan view. The seventeenth to twentieth banks BK17˜BK20 included in the fifth bank group BG5 may be arrayed in a first horizontal direction of the second memory region 150 in a plan view. The twenty-first to twenty-fourth banks BK21˜BK24 included in the sixth bank group BG6 may be arrayed in the first horizontal direction of the second memory region 150 in a plan view. The twenty-fifth to twenty-eighth banks BK25˜BK28 included in the seventh bank group BG7 may be arrayed in the first horizontal direction of the second memory region 150 in a plan view. The twenty-ninth to thirty-second banks BK29˜BK32 included in the eighth bank group BG8 may be arrayed in the first horizontal direction of the second memory region 150 in a plan view.

Memory regions included in each of the second, third and fourth semiconductor chips CHIP2, CHIP3 and CHIP4 may be realized to perform substantially the same operations as the first and second memory regions 140 and 150 illustrated in FIGS. 5 and 6. Thus, descriptions of the memory regions included in each of the second, third and fourth semiconductor chips CHIP2, CHIP3 and CHIP4 will be omitted hereinafter.

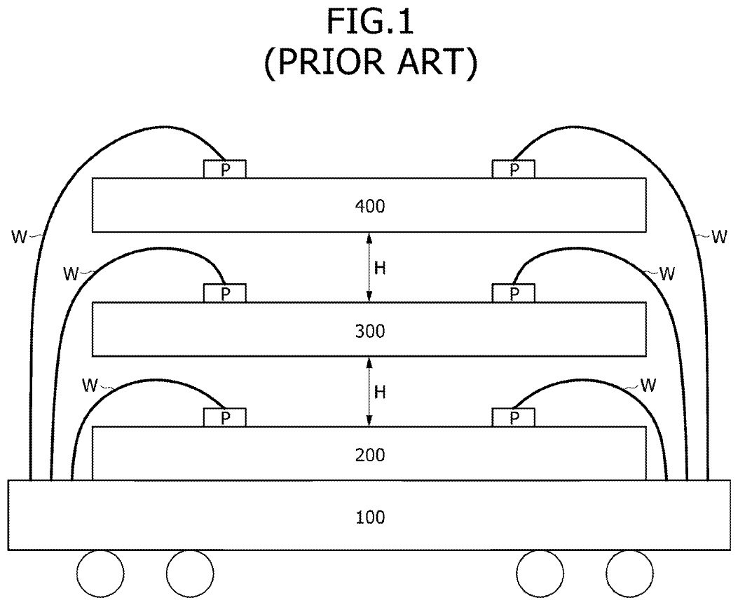

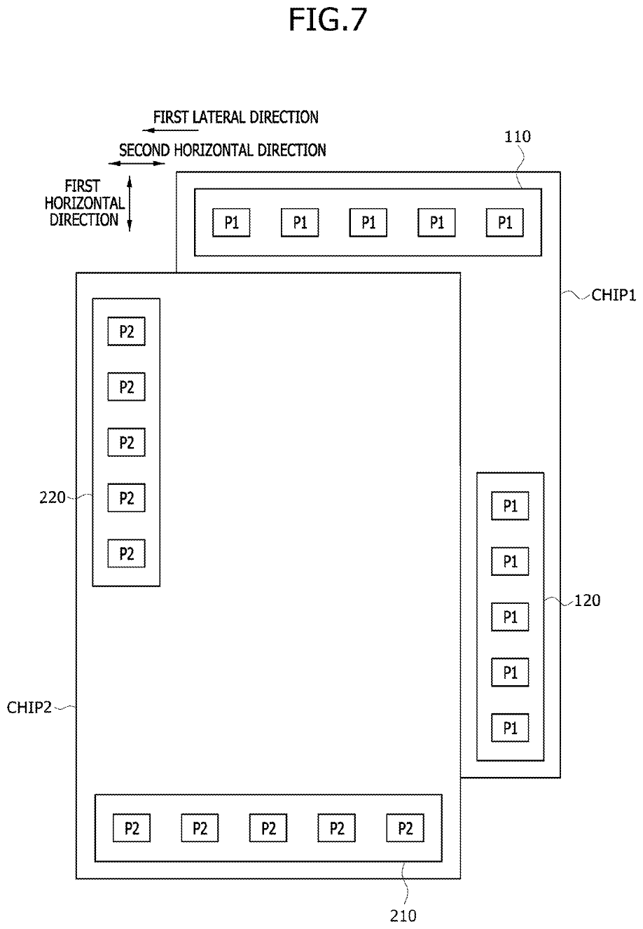

A stack structure of the first semiconductor chip CHIP1 and the second semiconductor chip CHIP2 included in the semiconductor package 1 of FIG. 1 will be described hereinafter with reference to FIG. 7.

The first semiconductor chip CHIP1 may be stacked on the substrate SUB such that the first pad region 110 is located at an upper edge region of the first semiconductor chip CHIP1 in a plan view and the second pad region 120 is located at a right edge region of the first semiconductor chip CHIP1 in a plan view.

The second semiconductor chip CHIP2 may be stacked on the first semiconductor chip CHIP1 such that the third pad region 210 is located at a lower edge region of the second semiconductor chip CHIP2 in a plan view and the fourth pad region 220 is located at a left edge region of the second semiconductor chip CHIP2 in a plan view. In such a case, the second semiconductor chip CHIP2 may be laterally offset relative to the first semiconductor chip CHIP1 to expose the first and second pad regions 110 and 120. Accordingly, the first and third pad regions 110 and 210 may be point symmetric with respect to a central point of the first and second semiconductor chips CHIP1 and CHIP2 when viewed from a plan view. Similarly, the second and fourth pad regions 120 and 220 may also be point symmetric with respect to the central point of the first and second semiconductor chips CHIP1 and CHIP2 when viewed from a plan view.

As described above, the second semiconductor chip CHIP2 may be stacked on the first semiconductor chip CHIP1 to be laterally offset in a first direction (i.e., first lateral direction). In such a case, although not shown in FIG. 7, the third semiconductor chip CHIP3 may be stacked on the second semiconductor chip CHIP2 to be laterally offset in a second direction opposite to the first direction such that the third and fourth pad regions 210 and 220 are exposed (i.e., second lateral direction). That is, the second, third and fourth semiconductor chips CHIP2, CHIP3 and CHIP4 may be vertically stacked on the first semiconductor chip CHIP1 in a zigzag fashion to expose their pad regions and to provide spaces enough for bonding the wires W1˜W4 to the pads P1˜P4 even without using any interposer-like elements disposed between the first to fourth semiconductor chips CHIP1, CHIP2, CHIP3 and CHIP4. As a result, a total thickness of the semiconductor package 1 may be reduced.

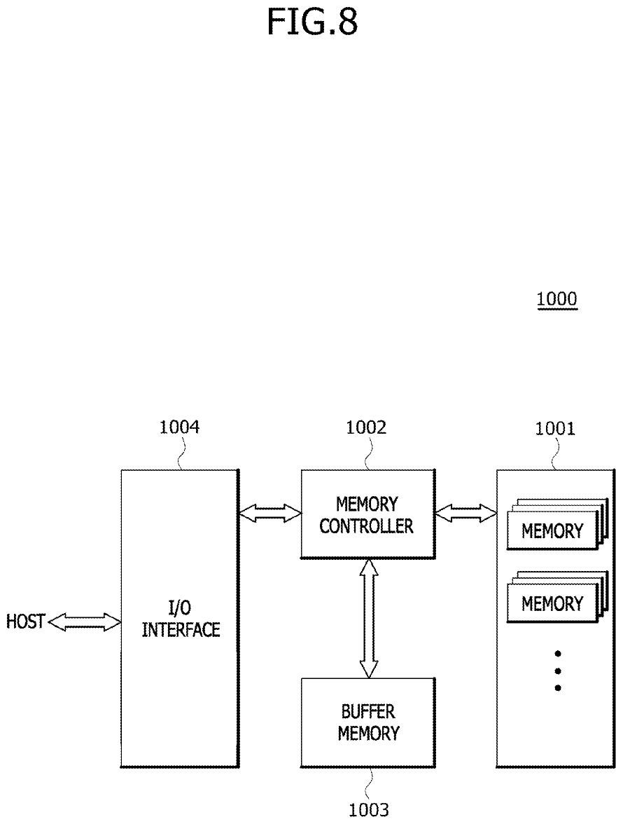

The semiconductor package 1 described with reference to FIGS. 2 to 7 may be applied to an electronic system that includes a memory system, a graphic system, a computing system, a mobile system, or the like. For example, as illustrated in FIG. 8, an electronic system 1000 according an embodiment may include a data storage circuit 1001, a memory controller 1002, a buffer memory 1003, and an input/output (I/O) interface 1004.

The data storage circuit 1001 may store data which are outputted from the memory controller 1002 or may read and output the stored data to the memory controller 1002, according to a control signal outputted from the memory controller 1002. The data storage circuit 1001 may include a nonvolatile memory that can retain their stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. Although FIG. 8 illustrates the memory controller 1002 with a single block, the memory controller 1002 may include one controller for controlling the data storage circuit 1001 and another controller for controlling the buffer memory 1003 comprised of a volatile memory.

The buffer memory 1003 may temporarily store the data to be processed by the memory controller 1002. That is, the buffer memory 1003 may temporarily store the data which are outputted from or to be inputted to the data storage circuit 1001. The buffer memory 1003 may store the data, which are outputted from the memory controller 1002, according to a control signal. The buffer memory 1003 may read and output the stored data to the memory controller 1002. The buffer memory 1003 may include the semiconductor package 1 illustrated in FIG. 2. The buffer memory 1003 may include a volatile memory such as a dynamic random access memory (DRAM), a mobile DRAM, or a static random access memory (SRAM).

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data outputted from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE).

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

What is claimed is:

1. A semiconductor package comprising:
a first semiconductor chip having a first pad region located at a first region of the first semiconductor chip and a second pad region located at a second region of the first semiconductor chip; and
a second semiconductor chip having a third pad region located at a first region of the second semiconductor chip and a fourth pad region located at a second region of the second semiconductor chip, wherein the second semiconductor chip is stacked on the first semiconductor chip and is offset in a horizontal direction relative to the first semiconductor chip.

2. The semiconductor package of claim 1, wherein the first and second semiconductor chips are vertically stacked in a zigzag fashion to expose the first, second, third and fourth pad regions.

3. The semiconductor package of claim 1,
wherein the first region of the first semiconductor chip is a first edge region of the first semiconductor chip;
wherein the second region of the first semiconductor chip is a second edge region adjacent to the first edge region of the first semiconductor chip;
wherein the first region of the second semiconductor chip is a first edge region of the second semiconductor chip; and
wherein the second region of the second semiconductor chip is a second edge region adjacent to the first edge region of the second semiconductor chip.

4. The semiconductor package of claim 1,
wherein the first pad region is disposed to extend in a first direction, and the second pad region is disposed to extend in a second direction, the second direction intersecting the first direction; and
wherein the third pad region is disposed to extend in the first direction, and the fourth pad region is disposed to extend in the second direction.

5. The semiconductor package of claim 1,
wherein the first and third pad regions are point symmetric with respect to a central point of the first and second semiconductor chips; and
wherein the second and fourth pad regions are point symmetric with respect to the central point of the first and second semiconductor chips.

6. The semiconductor package of claim 1, wherein the first semiconductor chip includes:
a first control circuit disposed to be adjacent to the first pad region, configured to decode a command to generate a first write signal and a first read signal, configured to decode an address to generate first and second selection addresses and first to fourth bank group addresses, and configured to receive or output data;
a first memory region located at one side of the first control circuit opposite to the first pad region and configured to include first to fourth bank groups which are activated according to the first to fourth bank group addresses if the first selection address is enabled; and
a second memory region located at one side of the first control circuit opposite to the first pad region and configured to include fifth to eighth bank groups which are activated according to the first to fourth bank group addresses if the second selection address is enabled.

7. The semiconductor package of claim 6,
wherein the first to eighth bank groups are arrayed in a second horizontal direction of the first and second memory regions; and
wherein a plurality of banks included in each of the first to eighth bank groups are arrayed in a first horizontal direction of the first or second memory region.

8. The semiconductor package of claim 6, wherein the first and second memory regions are disposed to be adjacent to each other.

9. The semiconductor package of claim 6, wherein the first to eighth bank groups are configured to receive or output the data through first to eighth input/output (I/O) lines, respectively.

10. The semiconductor package of claim 1, wherein the second semiconductor chip includes:
a second control circuit disposed to be adjacent to the third pad region, configured to decode a command to generate a second write signal and a second read signal, configured to decode an address to generate third and fourth selection addresses and fifth to eighth bank group addresses, and configured to receive or output data;
a third memory region located at one side of the second control circuit opposite to the third pad region and configured to include ninth to twelfth bank groups which are activated according to the fifth to eighth bank group addresses if the third selection address is enabled; and
a fourth memory region located at one side of the second control circuit opposite to the third pad region and configured to include thirteenth to sixteenth bank groups which are activated according to the fifth to eighth bank group addresses if the fourth selection address is enabled.

11. The semiconductor package of claim 10,
wherein the ninth to sixteenth bank groups are arrayed in a second horizontal direction of the third and fourth memory regions; and
wherein a plurality of banks included in each of the ninth to sixteenth bank groups are arrayed in a first horizontal direction of the third or fourth memory region.

12. The semiconductor package of claim 10, wherein the third and fourth memory regions are disposed to be adjacent to each other.

13. The semiconductor package of claim 10, wherein the ninth to sixteenth bank groups are configured to receive or output the data through ninth to sixteenth input/output (I/O) lines, respectively.

14. A semiconductor package comprising:
a first semiconductor chip configured to include a first pad region extending in a first direction and a second pad region extending in a second direction, the second direction intersecting the first direction, configured to receive a command and an address through the first pad region, and configured to receive or output data through the first pad region;
a second semiconductor chip configured to include a third pad region extending in the first direction and a second pad region extending in the second direction, configured to receive the command and the address through the third pad region, and configured to receive or output the data through the third pad region;
a third semiconductor chip configured to include a fifth pad region extending in the first direction and a sixth pad region extending in the second direction, configured to receive the command and the address through the fifth pad region, and configured to receive or output the data through the fifth pad region; and
a fourth semiconductor chip configured to include a seventh pad region extending in the first direction and an eighth pad region extending in the second direction, configured to receive the command and the address through the seventh pad region, and configured to receive or output the data through the seventh pad region,
wherein the second, third and fourth semiconductor chips are sequentially and vertically stacked on the first semiconductor chip in a zigzag fashion.

15. The semiconductor package of claim 14,
wherein the second semiconductor chip is offset in a first lateral direction relative to the first semiconductor chip;
wherein the third semiconductor chip is offset in a second lateral direction opposite to the first lateral direction relative to the second semiconductor chip; and
wherein the fourth semiconductor chip is offset in the first lateral direction relative to the third semiconductor chip.

16. The semiconductor package of claim 14,
wherein the second and fourth semiconductor chips are offset in a first lateral direction relative to the first and third semiconductor chips; and
wherein the first and third semiconductor chips are offset in a second lateral direction opposite to the first lateral direction relative to the second and fourth semiconductor chips.

17. The semiconductor package of claim 14, wherein the second, third and fourth semiconductor chips are stacked on the first semiconductor chip in a zigzag fashion to expose the first to eighth pad regions.

18. The semiconductor package of claim 14,
wherein the first pad region is located at a first edge region of the first semiconductor chip, and the second pad region is located at a second edge region of the first semiconductor chip adjacent to the first edge region of the first semiconductor chip;
wherein the third pad region is located at a first edge region of the second semiconductor chip, and the fourth pad region is located at a second edge region of the second semiconductor chip adjacent to the first edge region of the second semiconductor chip;
wherein the fifth pad region is located at a first edge region of the third semiconductor chip, and the sixth pad region is located at a second edge region of the third semiconductor chip adjacent to the first edge region of the third semiconductor chip; and
wherein the seventh pad region is located at a first edge region of the fourth semiconductor chip, and the eighth pad region is located at a second edge region of the fourth semiconductor chip adjacent to the first edge region of the fourth semiconductor chip.

19. The semiconductor package of claim 14, wherein the first semiconductor chip further includes:
a first control circuit disposed to be adjacent to the first pad region, configured to decode the command to generate a first write signal and a first read signal, configured to decode the address to generate first and second selection addresses and first to fourth bank group addresses, and configured to receive or output the data;
a first memory region located at one side of the first control circuit opposite to the first pad region and configured to include first to fourth bank groups which are activated according to the first to fourth bank group addresses if the first selection address is enabled; and
a second memory region located at one side of the first control circuit opposite to the first pad region and configured to include fifth to eighth bank groups which are activated according to the first to fourth bank group addresses if the second selection address is enabled.

20. The semiconductor package of claim 14, wherein the second semiconductor chip further includes:
a second control circuit disposed to be adjacent to the third pad region, configured to decode the command to generate a second write signal and a second read signal, configured to decode the address to generate third and fourth selection addresses and fifth to eighth bank group addresses, and configured to receive or output the data;
a third memory region located at one side of the second control circuit opposite to the third pad region and configured to include ninth to twelfth bank groups which are activated according to the fifth to eighth bank group addresses if the third selection address is enabled; and
a fourth memory region located at one side of the second control circuit opposite to the third pad region and configured to include thirteenth to sixteenth bank groups which are activated according to the fifth to eighth bank group addresses if the fourth selection address is enabled.

21. The semiconductor package of claim 14, wherein the third semiconductor chip further includes:
a third control circuit disposed to be adjacent to the fifth pad region, configured to decode the command to generate a third write signal and a third read signal, configured to decode the address to generate fifth and sixth selection addresses and ninth to twelfth bank group addresses, and configured to receive or output the data;
a fifth memory region located at one side of the third control circuit opposite to the fifth pad region and configured to include seventeenth to twentieth bank groups which are activated according to the ninth to twelfth bank group addresses if the fifth selection address is enabled; and
a sixth memory region located at one side of the third control circuit opposite to the fifth pad region and configured to include twenty-first to twenty-fourth bank groups which are activated according to the ninth to twelfth bank group addresses if the sixth selection address is enabled.

22. The semiconductor package of claim 14, wherein the fourth semiconductor chip further includes:
a fourth control circuit disposed to be adjacent to the seventh pad region, configured to decode the command to generate a fourth write signal and a fourth read signal, configured to decode the address to generate seventh and eighth selection addresses and thirteenth to sixteenth bank group addresses, and configured to receive or output the data;
a seventh memory region located at one side of the fourth control circuit opposite to the seventh pad region and configured to include twenty-fifth to twenty-eighth bank groups which are activated according to the thirteenth to sixteenth bank group addresses if the seventh selection address is enabled; and
an eighth memory region located at one side of the fourth control circuit opposite to the seventh pad region and configured to include twenty-ninth to thirty-second bank groups which are activated according to the thirteenth to sixteenth bank group addresses if the eighth selection address is enabled.
